(19) United States
(12) Patent Application Publication
(10) Pub. No.: US 2020/0373081 A1
(43) Pub. Date: Nov. 26, 2020

(54) INDUCTOR WITH METAL SHIELD

(71) Applicant: Intel Corporation, Santa Clara, CA (US)

(72) Inventors: Ranjul Balakrishnan, Bangalore (IN); Sagar Dubey, Bangalore (IN); Jackson Chung Peng Kong, Penang (MY); Anil Baby, Bangalore (IN)

(21) Appl. No.: 16/989,729

(22) Filed: Aug. 10, 2020

(51) Int. Cl. H01F 27/36; H01F 27/24; H01F 27/02; H01F 41/00; H05K 1/18; H05K 1/02

(52) U.S. Cl. CPC H01F 27/363; H01F 27/24; H01F 27/022; H05K 2201/1006; H05K 1/181; H05K 1/0237; H05K 2201/1003; H01F 41/005

(57) ABSTRACT

Embodiments of the present disclosure may relate to forming a metal shield around a molded ferrite inductor to reduce the electromagnetic energy radiated by the inductor during operation. The metal shield allows an inductor to be placed on a PCB with multiple signal routing layers below and close to the inductor, as well as micro strips on the surface of the PCB close to the inductor, to reliably route signals during operation. Other embodiments may be described and/or claimed.

### TECHNICAL FIELD

Embodiments of the present disclosure generally relate to the field of printed circuit board (PCB), in particular to the challenge of signal routing under a high current switching inductor.

### BACKGROUND

Computing platforms typically include printed circuit boards (PCB) that include power elements such as voltage regulators (VR) that include inductors. Currently, to avoid interference, signal routing underneath such elements is performed at the fourth inner layer onward of the PCB. Often, signal routing at the highest layer (the fourth layer) is limited only to non-critical or low speed signals (<1 Gps).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 illustrates an example of inductors with and without a metal shield, in accordance with various embodiments.

FIG. 2 illustrates an application of a metal shielded inductor and a non-shielded inductor on a PCB, in accordance with various embodiments.

FIG. 3 illustrates multiple perspective drawings of a shielded inductor at various stages of manufacture, in accordance with various embodiments.

FIG. 4 shows an example process for forming a metal shield around an inductor, in accordance with various embodiments.

FIG. 5 is a schematic of a computer system 500, in accordance with an embodiment of the invention.

### DETAILED DESCRIPTION

Embodiments of the present disclosure may relate to forming a metal shield around a molded ferrite inductor to reduce the electromagnetic energy radiated by the inductor during operation. The metal shield allows an inductor to be placed on a PCB with multiple signal routing layers below and close to the inductor, as well as micro strips on the surface of the PCB close to the inductor, to reliably route signals during operation.

In legacy implementations, signal routing under or proximate to high-current switching inductor components, with current flowing above 1 amp in general, in a PCB design is prohibited due to significant noise coupling from the magnetic field, or H-field, generated by the inductor components during operation. An inductor is one of the main components for a switching VR system for filtering ripples of incoming pulsed voltage. For example, Intel™ Core processors have 2-4 phases of such inductors for the primary voltage input rails, such as VCCIN and VCCIN_AUX. In these legacy implementations, reducing PCB board size provides a challenge to route critical signal paths close to the inductor (underneath it).

These legacy implementations, as described earlier, allow signal routing at the fourth layer of a PCB onwards for non-critical or low-speed signals, for example, less than 1 Gbps. No routing is allowed at PCB layers 1-3 to avoid magnetic field coupling noises that would lead to signal corruption and functional failures. This may also be referred to the inductor effect. Similarly, large distances, for example greater than 500 mils, is usually required in PCB design for any micro strip routed signals near the power inductor. This distance is determined based on the magnitude and frequency of the switching current through the inductor.

As a result, legacy implementations increase the PCB or motherboard layer count, and increase the keep-out-zone (KOZ) required to bypass the inductor effect. This restricts systems miniaturizations and interconnect density scaling. In addition, more expensive high density interconnect (HDI) PCB technology, for example 2-x-2+ or via-any-layer (VAL) is required over cost-effective 1-x-1/Type 3 solution.

Using the embodiments described herein, significant reduction of coupled noise may be achieved with a metal shielded inductor structure compared to widely used molded ferrite inductors structures, allowing signal traces to be routed in close proximity to the inductor in the micro strip layer. In addition, this allows signal traces to be routed below the first reference plane, for example layer 3 after the layer 2 ground plane, beneath the metal shielded inductor. As a result, this facilitates system miniaturization, allowing more dense routing near the switching inductor by reducing the KOZ constraints.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. It will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

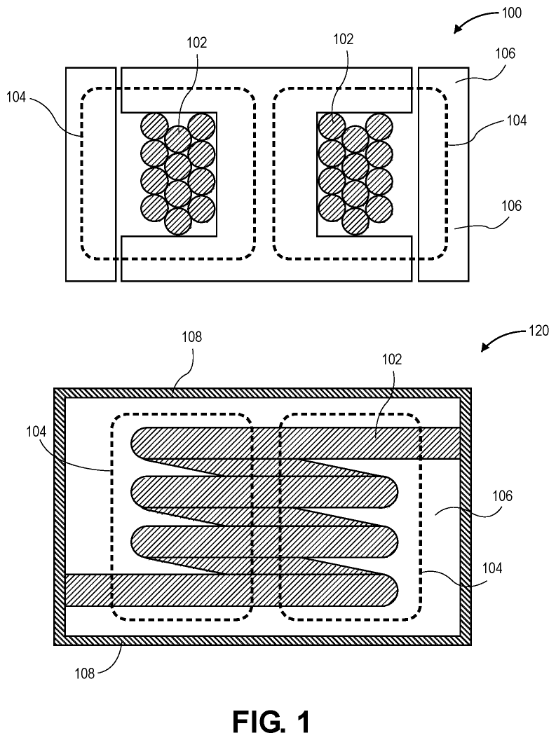

FIG. 1 illustrates an example of inductors with and without a metal shield, in accordance with various embodiments. Shielded core inductor 100 shows a cross-section of an inductor that includes an air-core coil 102 that is surrounded by a shielded core 104. The shielded core 104 may be partially surrounded by a ferrite material 106, which may be a soft magnetic metal powder. In this legacy implementation, the shielded core 104 is able to contain some of the magnetic field from escaping the inductor 100.

Metal shielded inductor 120 shows an embodiment that includes an air-core coil 102 surrounded by a shielded core 104. The shielded core 104 is embedded into a ferrite material 106, with a metal shield 108 surrounding the ferrite material 106. The metal shield 108 provides an enclosure to significantly block the field leakage outside of the metal shielded inductor 120. In addition, the metal shield 108 provides additional flexibility to the inductor 120, for example to ground the metal plate around the inductor to result in significant reduction of noise coupling to nearby circuits.

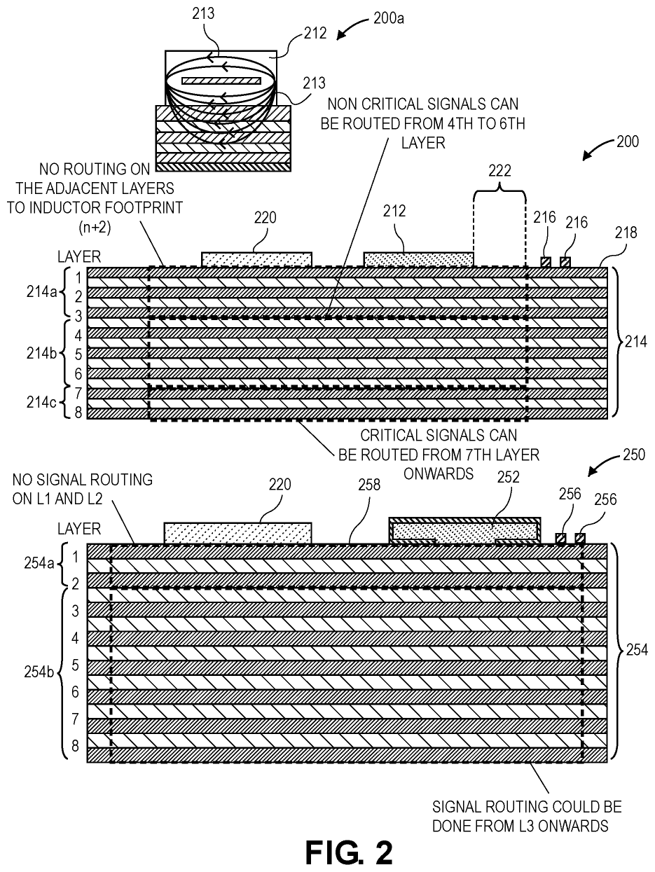

FIG. 2 illustrates an application of a metal shielded inductor and a non-shielded inductor on a PCB, in accordance with various embodiments. Legacy implementation 200 shows a legacy inductor 212 coupled with a PCB 214 that includes a plurality of layers used to route electrical signals within the PCB 214. These plurality of layers may include traces, which may also be referred to as strip lines. In addition, traces 216, which may be referred to as micro strips, may be placed on a surface 218 of the PCB 214 proximate to the inductor 212 at a distance called for by the KOZ 222 to route electrical signals along the surface 218. Other components, such as a field-effect transformer (FET) 220, may also be coupled to the PCB 214 proximate to the legacy inductor 212.

Diagram 200a shows legacy inductor 212, during operation, generating an electromagnetic field 213 that leaks outside the legacy inductor 212, including deep into the layers of the PCB 214, and extending laterally with respect to the legacy inductor 212. These resulting electromagnetic fields 213 during operation cause strip lines and traces within a PCB 214 layers, and traces 216, to generate coupling noise that causes these traces to no longer reliably carry electrical signals. In legacy implementations, a KOZ 222 of, for example, 300 mils, is required for micro strip 216 routing to minimize coupled noise to less than 15 my.

As a result, no routing is allowed on the adjacent layers 214a directly underneath the legacy inductor 212 due to the signal distortions resulting from the electromagnetic field 213. For layers 214b directly underneath the legacy inductor 212, noncritical signals may be routed from the fourth to the sixth layer. At layers 214c, critical signals can be routed from the seventh layer onward.

In legacy implementations, the inner layers of PCB 214 allowed for signal routing may be decided based on the number of shielded plane layers available under/near the power inductor, the thickness of these plane layers, punctures in in the plane layers with the proximity of inductor placement, the switching frequency, maximum current though the inductor, and the like. In general, the KOZ 222 for micro strips 216 is decided based on the magnitude and frequency of the switching current through the legacy inductor 212.

Metal shielded inductor implementation 250 shows an embodiment that includes a metal shielded inductor 252 coupled to the surface 258 of the PCB 254. As a result, micro strips 256 may be placed much closer to the metal shielded inductor 252 and be used to route critical signals. In addition, with respect to PCB 254, no signal routing may be done for layers 254a, while signal routing, including critical signals, may be routed in layers 254b. In embodiments, layers 254b may start with the third layer onwards after the second layer solid ground plane. In embodiments, the metal shielded inductor implementation 250, may result in a gain of approximately 180 mils routing space.

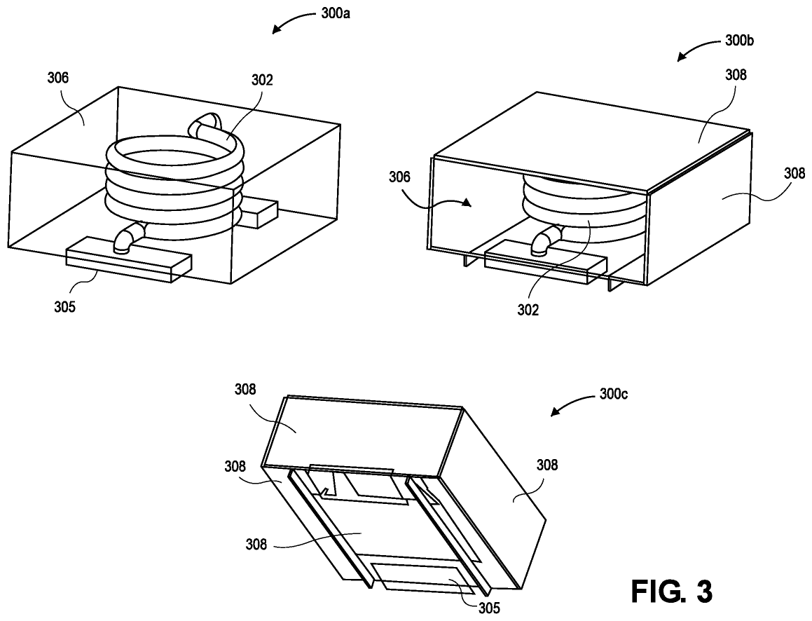

FIG. 3 illustrates multiple perspective drawings of a shielded inductor at various stages of manufacture, in accordance with various embodiments. Diagram 300a shows a first stage of creating a metal shielded inductor that includes an inductor coil 302, which is embedded in a ferrite material 306. These may be similar to coil 102 and ferrite 106 of FIG. 1. As shown, connectors 305 that are electrically coupled with the inductor coil 302 may appear along the bottom surface of the ferrite material 306. In embodiments, the connectors 305, which may be solder pads, are used to electrically couple the metal shielded inductor 252 to a surface 258 of a PCB 254 as shown in FIG. 2.

Diagram 300b shows a subsequent stage of the creation of a metal shielded inductor where the ferrite material 306 with the embedded inductor coil 302 is surrounded by a metal shield 308, which may be similar to metal shield 108 of FIG. 1. In embodiments, the metal shield 308, which may also referred to as a metal enclosure, may be made of copper or a copper alloy. In embodiments, it may completely surround the ferrite material 306. In embodiments, the metal shield 308 may have a thickness of 100 μm. As the thickness of the metal shield 308 increases, the greater the ability to reduce electromagnetic energy released during inductor operation has decreased surrounding electromagnetic interference.

Diagram 300c shows a different perspective, where the metal shield 308 surrounds the ferrite material 306 except for exposure of the connectors 305. In embodiments, various levels of electromagnetic energy may escape through these non-shielded connectors 305 depending upon the geometry and composition of the connectors 305.

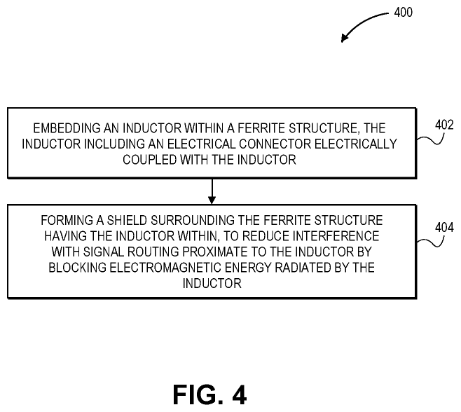

FIG. 4 shows an example process for forming a metal shield around an inductor, in accordance with various embodiments. The process 500 may be performed by one or more of the devices or techniques described herein including with respect to FIGS. 1-3.

At block 402, the process may include embedding an inductor within a ferrite structure, the inductor including an electrical connector electrically coupled with the inductor. In embodiments, the air-core coil 102 is embedded within the ferrite structure 106 of FIG. 1. In embodiments, electrical connectors 305 may be electrically coupled with the inductor coil 302 as shown in FIG. 3.

At block 404, the process may include forming a shield surrounding the ferrite structure having the inductor within, to reduce interference with signal routing proximate to the inductor by blocking electromagnetic energy radiated by the inductor. In embodiments, the shield may be the metal shield 308 of FIG. 3 that surrounds the ferrite structure 306. In embodiments, the metal shield may be made of copper or a copper alloy. The metal shield may have a varying thickness, for example, 100 μm or more. During operation, the metal shield will block electromagnetic energy radiating from the inductor.

In other embodiments, after the metal shield is formed around the ferrite inductor, the metal shielded conductor may be disposed in a location of the surface of the substrate of a PCB. For example, shielded inductor 252 may be disposed on a surface 258 of PCB 254 of FIG. 2. In embodiments, the shielded inductor 252 may be disposed proximate to a micro strip, where the micro strip is separated from the shielded inductor by 120 mills or less. In embodiments, the shielded inductor 252 may be disposed proximate to a strip line within the PCB, wherein the strip line is separated from the shielded inductor by 100 mills or less.

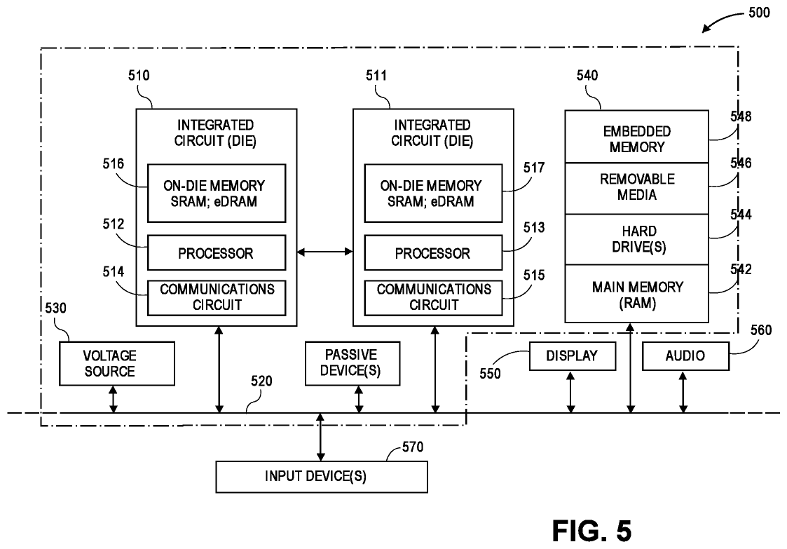

FIG. 5 is a schematic of a computer system 500, in accordance with an embodiment of the present invention. The computer system 500 (also referred to as the electronic system 500) as depicted can embody an inductor with a metal shield, according to any of the several disclosed embodiments and their equivalents as set forth in this disclosure. The computer system 500 may be a mobile device such as a netbook computer. The computer system 500 may be a mobile device such as a wireless smart phone. The computer system 500 may be a desktop computer. The computer system 500 may be a hand-held reader. The computer system 500 may be a server system. The computer system 500 may be a supercomputer or high-performance computing system.

In an embodiment, the electronic system 500 is a computer system that includes a system bus 520 to electrically couple the various components of the electronic system 500. The system bus 520 is a single bus or any combination of busses according to various embodiments. The electronic system 500 includes a voltage source 530 that provides power to the integrated circuit 510. In some embodiments, the voltage source 530 supplies current to the integrated circuit 510 through the system bus 520.

The integrated circuit 510 is electrically coupled to the system bus 520 and includes any circuit, or combination of circuits according to an embodiment. In an embodiment, the integrated circuit 510 includes a processor 512 that can be of any type. As used herein, the processor 512 may mean any type of circuit such as, but not limited to, a microprocessor, a microcontroller, a graphics processor, a digital signal processor, or another processor. In an embodiment, the processor 512 includes, or is coupled with, an inductor with a metal shield, as disclosed herein. In an embodiment, SRAM embodiments are found in memory caches of the processor. Other types of circuits that can be included in the integrated circuit 510 are a custom circuit or an application-specific integrated circuit (ASIC), such as a communications circuit 514 for use in wireless devices such as cellular telephones, smart phones, pagers, portable computers, two-way radios, and similar electronic systems, or a communications circuit for servers. In an embodiment, the integrated circuit 510 includes on-die memory 516 such as static random-access memory (SRAM). In an embodiment, the integrated circuit 510 includes embedded on-die memory 516 such as embedded dynamic random-access memory (eDRAM).

In an embodiment, the integrated circuit 510 is complemented with a subsequent integrated circuit 511. Useful embodiments include a dual processor 513 and a dual communications circuit 515 and dual on-die memory 517 such as SRAM. In an embodiment, the dual integrated circuit 510 includes embedded on-die memory 517 such as eDRAM.

In an embodiment, the electronic system 500 also includes an external memory 540 that in turn may include one or more memory elements suitable to the particular application, such as a main memory 542 in the form of RAM, one or more hard drives 544, and/or one or more drives that handle removable media 546, such as diskettes, compact disks (CDs), digital variable disks (DVDs), flash memory drives, and other removable media known in the art. The external memory 540 may also be embedded memory 548 such as the first die in a die stack, according to an embodiment.

In an embodiment, the electronic system 500 also includes a display device 550, an audio output 560. In an embodiment, the electronic system 500 includes an input device such as a controller 570 that may be a keyboard, mouse, trackball, game controller, microphone, voice-recognition device, or any other input device that inputs information into the electronic system 500. In an embodiment, an input device 570 is a camera. In an embodiment, an input device 570 is a digital sound recorder. In an embodiment, an input device 570 is a camera and a digital sound recorder.

As shown herein, the integrated circuit 510 can be implemented in a number of different embodiments, including a package substrate having an inductor with a metal shield, according to any of the several disclosed embodiments and their equivalents, an electronic system, a computer system, one or more methods of fabricating an integrated circuit, and one or more methods of fabricating an electronic assembly that includes a package substrate having an inductor with a metal shield, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates (multi-layer PCB) having an inductor with a metal shield embodiments and their equivalents. A foundation multi-layer PCB may be included, as represented by the dashed line of FIG. 5. Passive devices may also be included, as is also depicted in FIG. 5.

### EXAMPLES

Example 1 is an apparatus comprising: an inductor embedded within a ferrite structure; an electrical connector electrically coupled with the inductor; and a shield surrounding the ferrite structure having the inductor within, to block electromagnetic energy radiated by the inductor.

Example 2 may include the apparatus of example 1, wherein the apparatus is to be disposed at a location of a surface of a substrate of a printed circuit board (PCB).

Example 3 may include the apparatus of example 2, wherein the substrate includes multiple non-signal routing layers and signal routing layers underneath a location of the substrate, to which the apparatus is disposed.

Example 4 may include the apparatus of example 3, wherein at least one of the signal routing layer is less than three layers underneath the location of the substrate, to which the apparatus is disposed.

Example 5 may include the apparatus of example 1, wherein the inductor is part of a voltage regulator circuit.

Example 6 may include the apparatus of any one of examples 1-5, wherein the shield is formed with a metallic material.

Example 7 may include the apparatus of example 6, wherein the metallic material is copper or a copper alloy.

Example 8 may include the apparatus of example 6, wherein a thickness of the shield is at least 100 μm.

Example 9 is a method comprising: embedding an inductor within a ferrite structure, the inductor including an electrical connector electrically coupled with the inductor; and forming a shield surrounding the ferrite structure having the inductor within, to reduce interference with signal routing proximate to the inductor by blocking electromagnetic energy radiated by the inductor.

Example 10 may include the method of example 9, further comprising disposing the shielded inductor to a location of a surface of a substrate of a PCB.

Example 11 may include the method of example 10, wherein disposing the shielded inductor to the surface of the substrate further includes disposing the shielded inductor proximate to a micro strip, wherein the micro strip is separated from the shielded inductor by 120 mills or less.

Example 12 may include the method of example 10, wherein disposing the shielded inductor to the surface of the substrate further includes disposing the shielded inductor proximate to a strip line within the PCB, wherein the strip line is separated from the shielded inductor by 100 mills or less.

Example 13 may include the method of example 10, wherein disposing comprises disposing a voltage regulator or field effect transformer having the shielded inductor.

Example 14 may include the method of any one of examples 9-13, wherein forming the shield comprises forming the shield with at least 100 μm thickness of copper or a copper alloy.

Example 15 may be a system comprising: a printed circuit board (PCB) having a substrate with multiple non-signal routing layers and signal routing layers, wherein at least one of the signal routing layers is no more than three layers deep from a surface of the PCB; a shielded inductor electrically and physically coupled with a surface of the substrate of the PCB, the shielded inductor including: an inductor embedded within a metallic structure; an electrical connector electrically coupled with the inductor; and a shield surrounding the metallic structure having the inductor within, wherein the shield is to block electromagnetic energy radiated by the inductor to interfere with signal routing in the one signal routing layer.

Example 16 may include the system of example 15, wherein the shielded inductor is disposed in a location on the surface of the PCB above the non-signal routing layers and signal routing layers of the PCB.

Example 17 may include the system of example 15, wherein the surface of the substrate includes a micro strip, and wherein the micro strip and the shielded inductor are separated by 120 mills or less.

Example 18 may include the system of example 15, wherein the one signal routing layer of the PCB includes a strip line and wherein the strip line and the shielded inductor are separated by 100 mills or less.

Example 19 may include the system of example 15, wherein the system further includes a voltage regulator or a field effect transformer coupled to the surface of the substrate proximate to the shielded inductor.

Example 20 may include the system of any one of examples 15-19, wherein the shielded inductor is part of a voltage regulator circuit.

We claim:

1. An apparatus comprising:
an inductor embedded within a ferrite structure;
an electrical connector electrically coupled with the inductor; and
a shield surrounding the ferrite structure having the inductor within, to block electromagnetic energy radiated by the inductor.

2. The apparatus of claim 1, wherein the apparatus is to be disposed at a location of a surface of a substrate of a printed circuit board (PCB).

3. The apparatus of claim 2, wherein the substrate includes multiple non-signal routing layers and signal routing layers underneath a location of the substrate, to which the apparatus is disposed.

4. The apparatus of claim 3, wherein at least one of the signal routing layer is less than three layers underneath the location of the substrate, to which the apparatus is disposed.

5. The apparatus of claim 1, wherein the inductor is part of a voltage regulator circuit.

6. The apparatus of claim 1, wherein the shield is formed with a metallic material.

7. The apparatus of claim 6, wherein the metallic material is copper or a copper alloy.

8. The apparatus of claim 6, wherein a thickness of the shield is at least 100 μm.

9. A method comprising:
embedding an inductor within a ferrite structure, the inductor including an electrical connector electrically coupled with the inductor; and
forming a shield surrounding the ferrite structure having the inductor within, to reduce interference with signal routing proximate to the inductor by blocking electromagnetic energy radiated by the inductor.

10. The method of claim 9, further comprising disposing the shielded inductor to a location of a surface of a substrate of a PCB.

11. The method of claim 10, wherein disposing the shielded inductor to the surface of the substrate further includes disposing the shielded inductor proximate to a micro strip, wherein the micro strip is separated from the shielded inductor by 120 mills or less.

12. The method of claim 10, wherein disposing the shielded inductor to the surface of the substrate further includes disposing the shielded inductor proximate to a strip line within the PCB, wherein the strip line is separated from the shielded inductor by 100 mills or less.

13. The method of claim 10, wherein disposing comprises disposing a voltage regulator or field effect transformer having the shielded inductor.

14. The method of claim 9, wherein forming the shield comprises forming the shield with at least 100 μm thickness of copper or a copper alloy.

15. A system comprising:
a printed circuit board (PCB) having a substrate with multiple non-signal routing layers and signal routing layers, wherein at least one of the signal routing layers is no more than three layers deep from a surface of the PCB;
a shielded inductor electrically and physically coupled with a surface of the substrate of the PCB, the shielded inductor including:
an inductor embedded within a metallic structure;
an electrical connector electrically coupled with the inductor; and
a shield surrounding the metallic structure having the inductor within, wherein the shield is to block electromagnetic energy radiated by the inductor to interfere with signal routing in the one signal routing layer.

16. The system of claim 15, wherein the shielded inductor is disposed in a location on the surface of the PCB above the non-signal routing layers and signal routing layers of the PCB.

17. The system of claim 15, wherein the surface of the substrate includes a micro strip, and wherein the micro strip and the shielded inductor are separated by 120 mills or less.

18. The system of claim 15, wherein the one signal routing layer of the PCB includes a strip line and wherein the strip line and the shielded inductor are separated by 100 mills or less.

19. The system of claim 15, wherein the system further includes a voltage regulator or a field effect transformer coupled to the surface of the substrate proximate to the shielded inductor.

20. The system of claim 15, wherein the shielded inductor is part of a voltage regulator circuit.
